(19) United States
(12) Patent Application Publication
(10) Pub. No.: US 2025/0194442 A1
(43) Pub. Date: Jun. 12, 2025

(54) RESISTIVE MEMORY WITH ANGLED ELECTRODE PROFILE

(71) Applicant: International Business Machines Corporation, Armonk, NY (US)

(72) Inventors: Min Gyu Sung, Latham, NY (US); Soon-Cheon Seo, Glenmont, NY (US); Takashi Ando, Eastchester, NY (US); Ruilong Xie, Niskayuna, NY (US); Tao Li, Slingerlands, NY (US)

(21) Appl. No.: 18/532,551

(22) Filed: Dec. 7, 2023

(51) Int. Cl. H10N 70/00; H10B 63/00; H10N 70/20

(52) U.S. Cl. CPC H10N 70/8418; H10B 63/00; H10N 70/066; H10N 70/24; H10N 70/8265

(57) ABSTRACT

A resistive random access memory is provided including an asymmetrical or symmetrical bottom electrode which has an angled profile which forms an interface with a memory switching layer. The angled profile can include a slanted surface or one including a plurality of slanted surfaces that converge into a point. Bottom electrodes having such angled profiles provide more forming area, which can reduce forming voltage without area penalty. In some embodiments in which the slanted surfaces converge into a point, bottom electrodes having such an angled profile can also provide a more controlled area for the forming process to occur.

### BACKGROUND

The present application relates to semiconductor technology, and more particularly to a memory structure and a method of forming the same.

Non-volatile memory (NVM) or non-volatile storage is a type of computer memory that can retain stored information even after the power is removed. In contrast, volatile memory needs constant power in order to retain data. NVMs, such as, for example, resistive random access memory (ReRAM), phase change random access memory (PCRAM), and conductive bridge random access memory (CBRAM), are getting renewed attentions for potential applications to neuromorphic computing with in-memory processing capability which reduces power consumption significantly and eliminates data busing time between memory and the central processing unit (CPU) of conventional complementary metal oxide semiconductor (CMOS) based neuromorphic computing.

ReRAM (or sometimes referred to as RRAM) is considered as a promising technology for electronic synapse devices or memristors for neuromorphic computing as well as high-density and high-speed NVM applications. In neuromorphic computing applications, a resistance memory device such as ReRAM device can be used as a connection (i.e., synapse) between a pre-neuron and a post-neuron, representing the connection weight in form of device resistance.

### SUMMARY

A ReRAM is provided including an asymmetrical or symmetrical bottom electrode which has an angled profile which forms an interface with a memory switching layer. The angled profile can include a slanted surface or one including a plurality of slanted surfaces that converge into a point. Bottom electrodes having such angled profiles provide more forming area, which can reduce forming voltage without area penalty. In some embodiments in which the slanted surfaces converge into a point, bottom electrodes having such an angled profile can also provide a more controlled area for the forming process to occur.

In one aspect of the present application, a memory structure is provided. In one embodiment, the memory structure includes an asymmetrical first electrode structure having a slanted surface, a memory switching layer forming an interface with the slanted surface of the asymmetrical first electrode structure, and a second electrode structure located on the memory switching layer.

In another embodiment, the memory structure includes a symmetrical first electrode structure having an angled profile including a plurality of slanted surfaces that converge into a point, a memory switching layer forming an interface with the angled profile of the symmetrical first electrode structure, and a second electrode structure located on the memory switching layer.

In another aspect of the present application, a method of forming a memory structure is provided. In one embodiment, the method includes forming a first electrode pillar in an opening located in an interlayer dielectric layer, performing an angled etching process to convert the first electrode pillar into a first electrode structure having an angled profile, forming a memory switching liner on physically exposed surfaces of the first electrode structure and the first interlayer dielectric layer, forming a conductive electrode material layer on the memory switching liner, and patterning the conductive material layer and the memory switching liner to provide a second electrode structure and a memory switching layer, respectively. In embodiments, the angled etching process is performed with rotation. In other embodiments, the angled etching process is performed without rotation.

### BRIEF DESCRIPTION OF THE DRAWINGS

FIG. 1 is a cross sectional view of an exemplary structure that can be employed in accordance with an embodiment of the present application, the exemplary structure includes a first electrically conductive layer, and a first interlayer dielectric (ILD) layer having an opening formed therein that physically exposes a surface of the first electrically conductive layer.

FIG. 2 is a cross sectional view of the exemplary structure illustrated in FIG. 1 after forming a first conductive electrode material layer on the first ILD layer and within the opening.

FIG. 3 is a cross sectional view of the exemplary structure illustrated in FIG. 2 after removing the first conductive electrode material layer that is located outside the opening and on the first ILD layer, while maintaining the first conductive electrode material layer in the opening; the maintained first conductive electrode material layer can be referred to as a first electrode pillar.

FIG. 4 is a cross sectional view of the exemplary structure illustrated in FIG. 3 after performing an angled etching process to convert the first electrode pillar into a first electrode structure having an angled profile.

FIG. 5 is a cross sectional view of the exemplary structure illustrated in FIG. 4 after forming a memory switching liner on physically exposed surfaces of the first electrode structure and the first ILD layer.

FIG. 6 is a cross sectional view of the exemplary structure illustrated in FIG. 5 after forming a second conductive electrode material layer on the memory switching liner.

FIG. 7 is a cross sectional view of the exemplary structure illustrated in FIG. 6 after performing an optional planarization process.

FIG. 8 is a cross sectional view of the exemplary structure illustrated in FIG. 6 or FIG. 7 after patterning the second conductive material layer and the memory switching liner to provide a second electrode structure and a memory switching layer, respectively, and forming an encapsulation layer.

FIG. 9 is a cross sectional view of the exemplary structure illustrated in FIG. 8 after forming a second ILD layer having a via contact structure embedded therein, and forming a second electrically conductive layer on physically exposed surfaces of each of the second ILD layer and the via contact structure.

FIG. 10 is a cross sectional view the exemplary structure illustrated in FIG. 3 after performing a rotating angled etching process to convert the first electrode pillar into a first electrode structure having an angled profile.

FIGS. 11A, 11B, 11C, 11D and 11E depict various first electrode structures that can be formed utilizing the rotating angled etching process.

FIG. 12A is a cross sectional view of the exemplary structure shown in FIG. 10 after further ReRAM device processing.

FIG. 12B is an enlarged view of first electrode structure, memory switching layer, and second electrode structure shown in FIG. 12A and depicting a filament forming area created by applying a forming voltage to the structure.

FIG. 13 is a cross sectional view of another exemplary structure in accordance with the present application, this another exemplary structure includes a first electrically conductive layer, a first ILD layer having an opening formed therein, and a bilayer structure present in the opening, the bilayer structure including a bottom first conductive electrode material layer and a top first conductive electrode material layer.

FIG. 14 is a cross sectional view the exemplary structure illustrated in FIG. 13 after performing a rotating angled etching process to convert the bilayer structure into a first electrode bilayer structure having an angled profile.

FIG. 15 is a cross sectional view of the exemplary structure shown in FIG. 14 after further ReRAM device processing.

FIG. 16 is a cross sectional view of yet another exemplary structure in accordance with the present application, this another exemplary structure includes a first electrically conductive layer, a first ILD layer having an opening formed therein, and a bottom first conductive electrode pillar in the opening.

FIG. 17 is a cross sectional view the exemplary structure illustrated in FIG. 16 after performing a rotating angled etching process to convert the bottom first conductive electrode pillar into a first bottom conductive electrode structure having an angled profile.

FIG. 18 is a cross sectional view the exemplary structure illustrated in FIG. 17 after forming a bottom second conductive electrode layer.

FIG. 19 is a cross sectional view of the exemplary structure shown in FIG. 18 after further ReRAM device processing.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

Conventional filamentary switching ReRAM devices require a forming step to create soft breakdown. In such ReRAM devices, the forming voltage scales as a function of switching area. For example, as the switching area scales down, the forming voltages increase. This increase in forming voltages typically requires the use of an additional external device that is capable of delivering high voltages necessary for such filamentary switching. The use of an external voltage device results in additional power consumption. Lower forming voltages can be used in cases in which the switching area is increased. This approach however can lead to an undesirable area penalty.

In addition to the above, as conductive filaments are created randomly within a memory switching layer that is located on a bottom electrode, it is challenging to control the filament location during the forming process. This can lead to forming voltage variation and subsequent switching variation.

The above problems (i.e., high forming voltages, area penalty, and voltage and switching variations) associated with conventional filamentary switching ReRAM devices can be reduced and, in some cases, eliminated by providing a ReRAM having an asymmetrical or symmetrical bottom electrode that has an angled profile. In the present application, the bottom electrode can also be referred to as a first electrode structure. In embodiments in which an asymmetrical bottom electrode is employed, the angled profile is a slanted surface. In embodiments in which a symmetrical bottom electrode is employed, the angled profile including a plurality of slanted surfaces that converge at a point (or tip). For both the asymmetrical and symmetrical bottom electrodes of the present application, the angled profile provides more forming area, which can reduce forming voltage without area penalty. For the symmetrical bottom electrodes of the present application, the point (or tip in which the slanted surfaces converge) can provide a more controlled area for the forming process to occur. In embodiments, the symmetrical bottom electrode can have a shape of a flame, a triangular pyramid, a square pyramid, a multiple faceted pyramid or a cone. The asymmetrical and symmetrical bottom electrodes are all solid structures, not hollow as is the case with some prior art bottom electrodes having a triangular shape. A memory array can be provided in which the ReRAMs can have a same or different angled profile bottom electrode.

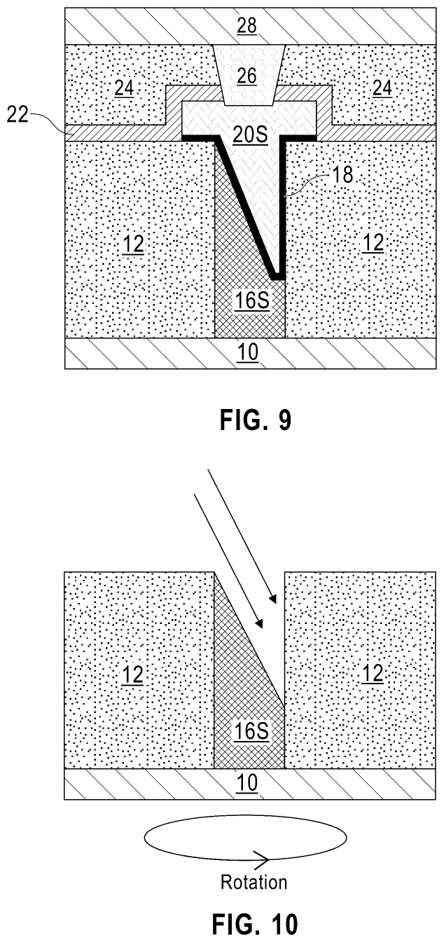

In one embodiment and as is illustrated in FIG. 9, a memory structure is provided that includes an asymmetrical first electrode structure 16S having a slanted surface, a memory switching layer 18 forming an interface with the slanted surface of the asymmetrical first electrode structure 16S, and a second electrode structure 20S located on the memory switching layer 18. Collectively, the asymmetrical first electrode structure 16S, the memory switching layer 18, and the second electrode structure 20S form a ReRAM of the present application. For this embodiment in which an asymmetrical first electrode structure 16S is employed, the angled profile provided by the sloped surface of the first electrode structure 16S provides more forming area, which can reduce forming voltage without area penalty.

In some embodiments and as depicted in FIG. 9, the slanted surface of the asymmetrical first electrode structure 16S extends in a direction from a topmost surface down to a planar sub-surface of the asymmetrical first electrode structure. In some embodiments and as depicted in FIG. 9, the direction is from left to right. In other embodiments (not shown but readily discernable by FIG. 9), the direction is from right to left.

In some embodiments and as depicted in FIG. 9, the memory structure can further include a first electrically conductive layer 10 in electrical contact with the asymmetrical first electrode structure 16S, and a second electrically conductive layer 28 in electrical contact with the second electrode structure 20S by means of a via contact structure 26. This aspect of the present application provides the wiring of the ReRAM of the present application.

In some embodiments and as depicted in FIG. 9, the memory structure can further include an encapsulation layer 22 located adjacent to the memory switching layer 18, the second electrode structure 20S and the via contact structure 26. The encapsulation layer 22 can provide electrically isolation and, in some cases, passivation to the memory switching layer 18 and the second electrode structure 20S of the ReRAM.

In some embodiments and as depicted in FIG. 9, the asymmetrical first electrode structure 16S, a first portion of the memory switching layer 18, and a first portion of the second electrode structure 20S are embedded in a first interlayer dielectric layer 12, and the first interlayer dielectric layer 12 is located on a surface of the first electrically conductive structure 10.

In some embodiments and as depicted in FIG. 9, the memory structure can further include a second interlayer dielectric layer 24 located above the first interlayer dielectric layer 12 and adjacent to second portion of the memory switching layer 18, a second portion of the second electrode structure 20S and the via contact structure 26, and wherein the second electrically conductive layer 28 is located on top of the second interlayer dielectric layer 24.

In some embodiments and as depicted in FIG. 9, the memory switch layer 18 has a sidewall that is vertically aligned with a sidewall of the second electrode structure 20S.

In another embodiment and as shown in FIG. 12A, the memory structure includes a symmetrical first electrode structure 16S having angled profile including a plurality of slanted surfaces that converge at point (or tip), a memory switching layer 18 forming an interface with the angled profile of the symmetrical first electrode structure 16S, and a second electrode structure 20S located on the memory switching layer 18. It is noted that the memory structure shown in FIGS. 15 and 19 also include a symmetrical first electrode structure having such an angled profile as the one depicted in FIG. 12A. In both FIGS. 15 and 19, the symmetrical first electrode structure is a first electrode bilayer structure, as defined herein below. For this embodiment in which an asymmetrical first electrode structure is employed, the angled profile provides more forming area, which can reduce forming voltage without area penalty. Also, and because of the present of the point (or tip) in the symmetrical bottom electrode structures, a more controlled area for the filament forming process to occur is provided.

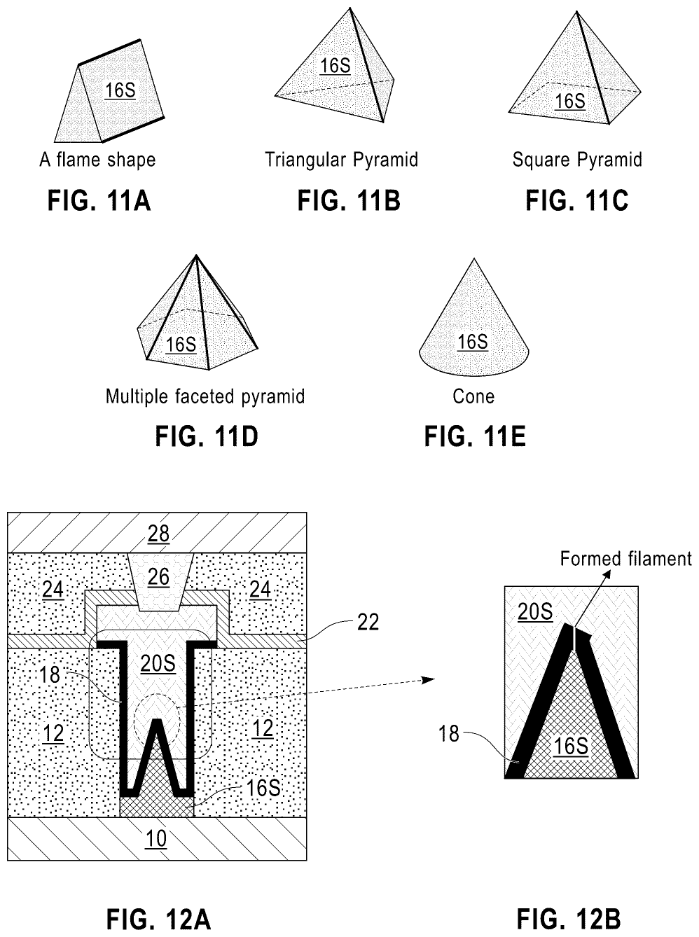

In some embodiments and as depicted in FIGS. 11A-11E, the symmetrical first electrode is in the shape of a flame, a triangular pyramid, a square pyramid, a multiple faceted pyramid or a cone.

In some embodiments and as depicted in 12A, the symmetrical first electrode is solid and composed of a single electrode material.

In some embodiments and as depicted in FIG. 15, the symmetrical first electrode includes a bilayer structure of a bottom first electrode structure 30S, and a top first electrode structure 32S.

In some embodiments and as depicted in FIG. 19, the symmetrical first electrode includes a bilayer structure of a first bottom electrode structure 34S and a bottom second electrode structure 26S.

In some embodiments such as depicted in FIGS. 12A, 15 and 19, the memory structure can further include a first electrically conductive layer 10 in electrical contact with the symmetrical first electrode structure, and a second electrically conductive layer 28 in electrical contact with the second electrode structure 20S by means of a via contact structure 26.

In some embodiments such as depicted in FIGS. 12A, 15 and 19, the memory structure can further include an encapsulation layer 22 located adjacent to the memory switching layer 18, the second electrode structure 20S and the via contact structure 26.

In some embodiments such as depicted in FIGS. 12A, 15 and 19, the symmetrical first electrode structure, a first portion of the memory switching layer 18, and a first portion of the second electrode structure 20S are present in a first interlayer dielectric layer 12, and the first interlayer dielectric layer 12 is located on a surface of the first electrically conductive structure 10.

In some embodiments such as depicted in FIGS. 12A, 15 and 19, the memory structure can further include a second interlayer dielectric layer 28 located above the first interlayer dielectric layer 12 and adjacent to a second portion of the memory switching layer 18, a second portion of the second electrode structure 20S and the via contact structure 26, wherein the second electrically conductive layer 28 is located on top of the second interlayer dielectric layer 24.

In another aspect of the present application, a method of forming a memory structure. In one embodiment the method includes forming a first electrode pillar in an opening located in an interlayer dielectric layer, performing an angled etching process to convert the first electrode pillar into a first electrode structure having an angled profile, forming a memory switching liner on physically exposed surfaces of the first electrode structure and the first interlayer dielectric layer, forming a conductive electrode material layer on the memory switching liner, and patterning the conductive material layer and the memory switching liner to provide a second electrode structure and a memory switching layer, respectively. In embodiments, the angled etching process is performed with rotation. In other embodiments, the angled etching process is performed without rotation.

These and other aspect of the present application will now be described in greater detail. It is noted that the drawings of the present application illustrate a memory device area in which at least one ReRAM will be formed. A non-memory device area may be located laterally adjacent to the memory device area illustrated in the drawings of the present application.

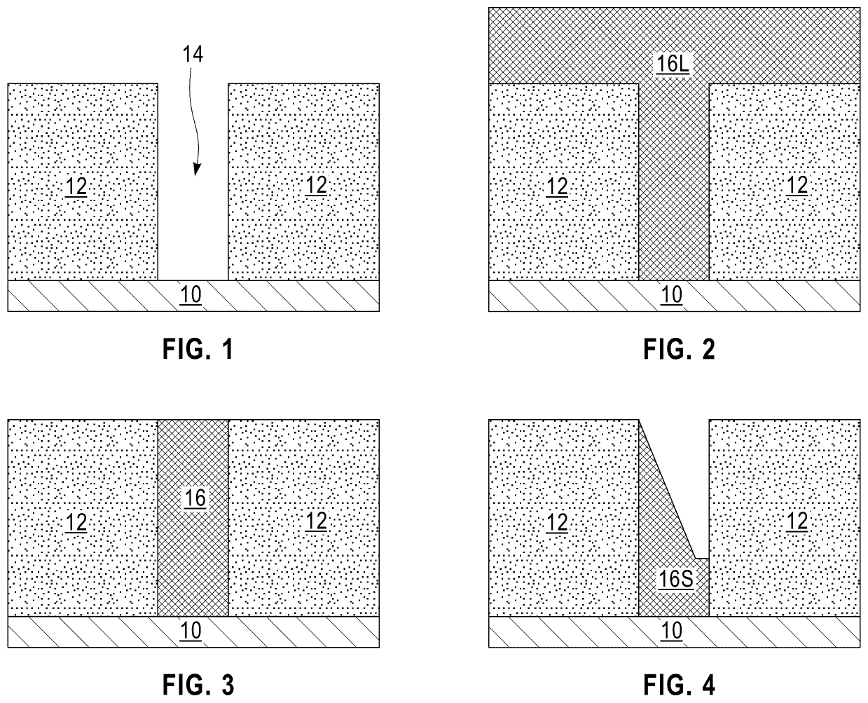

Referring first to FIG. 1, there is illustrated an exemplary structure that can be employed in accordance with an embodiment of the present application. The illustrated exemplary structure shown in FIG. 1 includes a first electrically conductive layer 10, and a first ILD layer 12 having an opening 14 formed therein that physically exposes a surface of the first electrically conductive layer 10. Although one opening 14 is depicted in FIG. 1, the present application can be employed when a plurality of openings is formed into the first ILD layer 12, each of the openings would physically expose a surface of the underlying first electrically conductive layer 10.

The first electrically conductive layer 10 is composed of an electrically conductive metal or an electrically conductive metal alloy. The electrically conductive metal that provides first electrically conductive layer 10 can include, for example, copper (Cu), aluminum (Al), tungsten (W), cobalt (Co), ruthenium (Ru), nickel (Ni), iridium (Ir), or rhodium (Rh). An example of an electrically conductive alloy that provides the first electrically conductive layer 10 includes a Cu—Al alloy. The first electrically conductive layer 10 can be composed of a single electrically conductive material or a multilayered stack of at least two different electrically conductive materials. In some embodiments, the first electrically conductive layer 10 can be present within any interconnect level of a back-end-of-the-line (BEOL) structure. In other embodiments, the first electrically conductive layer 10 can be present in a front-end-of-the-line (FEOL) level or a middle-of-the-line level (MOL).

The first electrically conductive layer 10 can be formed by a deposition process such as, for example, chemical vapor deposition (CVD), plasma enhanced chemical vapor deposition (PECVD), atomic layer deposition (ALD), physical vapor deposition (PVD), sputtering, chemical solution deposition or plating.

The first ILD layer 12 is composed of a dielectric material. The dielectric material that provides first ILD layer 12 can be composed of, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer, or any combination thereof. The term “low-k” as used throughout the present application denotes a dielectric material that has a dielectric constant of less than 4.0 (all dielectric constants mentioned herein are relative to a vacuum unless otherwise noted). The first ILD layer 12 can be formed by deposition of the dielectric material (e.g., by CVD, PECVD or spin-on coating). In some embodiments, a planarization process such as, for example, chemical mechanical polishing (CMP) and/or grinding can follow the deposition of the dielectric material that provides the first ILD layer 12. In some embodiments, the planarization step is omitted and the first ILD layer 12 is formed by deposition of the dielectric material.

The opening 14 can be formed by lithography and etching. Lithography includes forming a photoresist material on a layer or stack of material layers that need to be patterned, exposing the photoresist material to a desired pattern of irradiation and thereafter developing the exposed photoresist material utilizing a conventional resist developer. The developed photoresist material has a desired pattern that is then transferred to the layer or stack of material layers that need to be patterned by etching. Etching can include dry etching and/or chemical wet etching. In one embodiment, a dry etch such as, for example, reactive ion etching (RIE), ion beam etching (IBE), plasma etching or any combination thereof can be used to transfer the pattern to the layer or stack of material layers that need to be patterned. In illustrated embodiment, this etch etches through an entirety of the first ILD layer 12.

Referring now to FIG. 2, there is illustrated the exemplary structure shown in FIG. 1 after forming a first conductive electrode material layer 16L on the first ILD layer 12 and within the opening 14. As is shown, a bottommost surface of the first conductive electrode material layer 16L directly contacts the physically exposed surface of the first electrically conductive layer 10. The first conductive electrode material layer 16L is composed of an electrode material including, for example, Ta, TaN, Ti, TiN, Ru, RuN, RuTa, RuTaN, Cu, Co, CoWP, CoN, W, WN or any combination thereof. In some embodiments, the electrode material that provides the first conductive electrode material layer 16L can be oxygen deficient. The first conductive electrode material layer 16L can be formed by a deposition process such as, for example, CVD, PECVD, ALD, PVD, sputtering, electroplating or electroless plating.

Referring now to FIG. 3, there is illustrated the exemplary structure shown in FIG. 2 after removing the first conductive electrode material layer 16L that is located outside the opening 14 and on the first ILD layer 12, while maintaining the first conductive electrode material layer 16L in the opening 14; the maintained first conductive electrode material layer 16L can be referred to as a first electrode pillar 16. The first electrode pillar 16 has a planar bottommost surface and a planar topmost surface. The planar topmost surface of the first electrode pillar 16 is substantially coplanar with a topmost surface of the first ILD layer 12, while the planar bottommost surface of the first electrode pillar 16 is substantially coplanar with a bottommost surface of the first ILD layer 12. This removal step of the present application includes a planarization process such as, for example, CMP and/or grinding.

Referring now to FIG. 4, there is illustrated the exemplary structure shown in FIG. 3 after performing an angled etching process to convert the first electrode pillar 16 into a first electrode structure 16S having an angled profile. First electrode structure 16S can also be referred to as bottom electrode structure. By “angled profile”, it is meant the first electrode structure 16S has at least one slanted surface. In the embodiment illustrated in FIG. 4, the angled etching process forms a single slanted surface. This single slanted surface is opposite a planar bottommost surface of the first electrode structure 16S. In embodiments, the slope surface can go from left to right as depicted in FIG. 4, or from right to left (not depicted) depending on the angle of the etch. The first electrode structure 16S of this embodiment is asymmetrically shaped. By “asymmetrical” it is meant two sides or halves of the structure, as designated by a vertical line passing through a middle portion of the structure are not the same. The slanted surface provides more forming area, which can reduce forming voltages without causing area penalty. The slanted surface of the bottom electrode structure 16S will subsequently be interfaced with memory switching layer 18. In this embodiment, the slanted surface begins at a topmost surface of the bottom electrode structure 16S and extends down to a planar sub-surface of the bottom electrode structure 16S is a slanted fashion. In the present application, a “sub-surface” of a structure/material is a surface that is located between a topmost surface of the structure/material to a bottom surface of the same structure/material. The direction of the slant can be from left to right, or from right to left, depending on the degree that the angled etch was performed.

In some embodiments, the angled etching process includes an angled RIE process. The dry etch chemistry can include, for example, a mixture of Ar/CHF₃ or a mixture of Ar and BCl₃. In other embodiments, a direction etching process can be used to provide the first electrode structure 16S having the angled profile. Note that the angled etching process of this embodiment does not include any rotation of the underlying wafer.

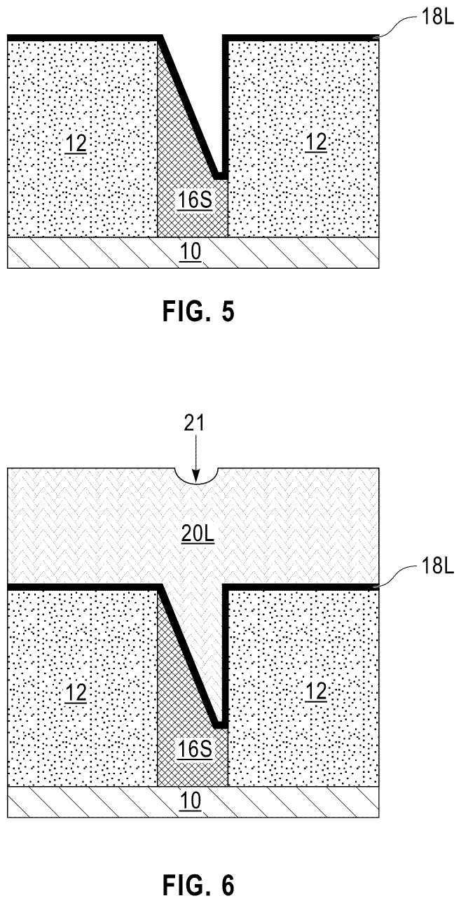

Referring now to FIG. 5, there is illustrated the exemplary structure shown in FIG. 4 after forming a memory switching liner 18L on physically exposed surfaces of the first electrode structure 16S and the first ILD layer 12. The memory switching liner 18L is composed of a dielectric material such as a dielectric metal oxide that has a dielectric constant of 4.0 or greater. Examples of dielectric metal oxides that can be employed as the memory switching liner 18L include, but are not limited to, hafnium oxide, tantalum oxide, titanium oxide, aluminum oxide, silicon dioxide or combinations thereof. In some embodiments, hydrogen can be present in the dielectric material that provides the memory switching liner 18L. The dielectric material that provides the memory switching liner 18L can be formed utilizing a deposition process such as, for example, CVD, PECVD, ALD, chemical solution deposition or evaporation. The memory switching liner 18L can have a thickness from 1 nm to 50 nm; other thicknesses however are contemplated can be used as the thickness of the memory switching liner 18L. The memory switching liner 18L follows the contour of the first electrode structure 16S.

Referring now to FIG. 6, there is illustrated the exemplary structure shown in FIG. 5 after forming a second conductive electrode material layer 20L on the memory switching liner 18L. The second conductive electrode material layer 20L is composed of one of the electrode materials mentioned above for the first conductive electrode material layer 16L. In some embodiment, the electrode material that provides the second conductive electrode material layer 20L can be compositionally the same as the electrode material that provides the first conductive electrode material layer 16L. In some embodiments, the electrode material that provides the second conductive electrode material layer 20L can be compositionally different than the electrode material that provides the first conductive electrode material layer 16L. The second conductive electrode material layer 20L can be composed of a single layer of electrode material or a multilayered layered stack of at least two different electrode materials. The second conductive electrode material layer 20L can be formed by a deposition process such as, for example, CVD, PECVD, ALD, PVD, sputtering, electroplating or electroless plating. In some embodiments, a divot 21 is formed in the second conductive electrode material layer 20L in a region of an upper surface of the as-deposited second conductive electrode material layer 20L that is located directly above the opening 14.

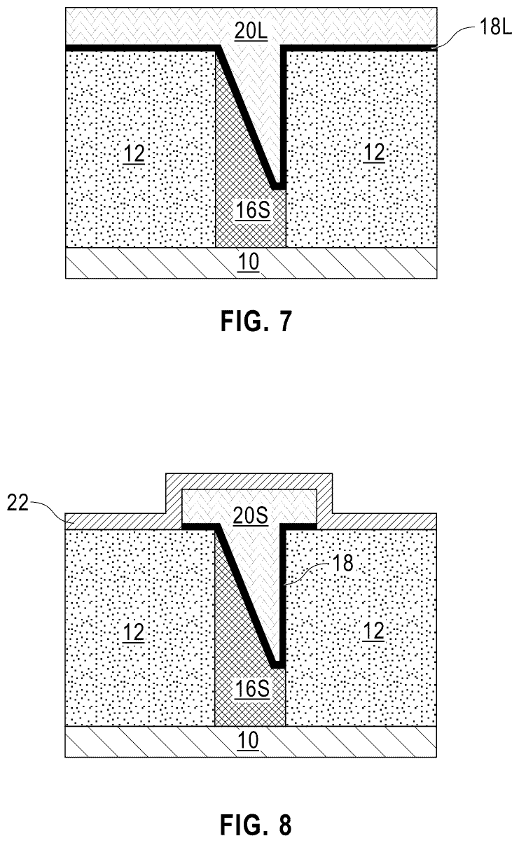

Referring now to FIG. 7, there is illustrated the exemplary structure shown in FIG. 6 after performing an optional planarization process. In some embodiments, this planarization process is omitted. When performed, the planarization process can include CMP and/or grinding. The planarization process is used to thin the as-deposited second conductive electrode material layer 20L and it can be used to remove any divot 21 that is present in the as-deposited second conductive electrode material layer 20L.

Referring now to FIG. 8, there is illustrated the exemplary structure shown in FIG. 6 or FIG. 7 after patterning the second conductive material layer 20L and the memory switching liner 18L to provide a second electrode structure 20S and a memory switching layer 18, respectively, and forming an encapsulation layer 22. This patterning step of the present application includes lithography and etching as defined above. The etch can be a single etch or multiple etching steps can used in providing the structure illustrated in FIG. 8. The second electrode structure 20S (which can represent a top electrode structure) includes an unetched portion of the second conductive material layer 20L, while the memory switching layer 18 includes an unetched portion of the memory switching liner 18L.

After patterning, the second electrode structure 20S has a sidewall that is vertically aligned with a sidewall of the underlying memory switching layer 18. At this point of the present application, the memory switching layer 18 is electrically insulating and during operational use (which includes a filament forming process in which a voltage is applied to the structure) a filament which is electrically conducting can be formed in the memory switching layer 18.

This patterning step forms a ReRAM in accordance with the present application. The ReRAM includes the first electrode structure 16S having the angled profile, the memory switching layer 18, and the second electrode structure 20S. As is illustrated, the memory switching layer 18 is sandwiched between the first electrode structure 16S and the second electrode structure 20S. The second electrode structure 20S has a planar topmost surface and a bottom surface that is sloped in an opposite direction to the sloped surface of the first electrode structure 16S.

The encapsulation layer 22 is composed of a dielectric material that can provide passivation to each ReRAM of the present application. In one embodiment, the encapsulation layer 22 is composed of silicon nitride. In another embodiment, the encapsulation layer 22 can be composed of a dielectric material that contains atoms of silicon, carbon and hydrogen. In some embodiments, and in addition to atoms of carbon and hydrogen, the dielectric material that provides the encapsulation layer 22 can include atoms of at least one of nitrogen and oxygen. In other embodiments, and in addition to atoms of silicon, nitrogen, carbon and hydrogen, the dielectric material that provides the encapsulation layer 22 can include atoms of boron. In one example, the encapsulation layer 22 can be composed of an nBLOK dielectric material that contains atoms of silicon, carbon, hydrogen, nitrogen and oxygen. In alternative example, the encapsulation layer 22 can be composed of a SiBCN dielectric material that contains atoms of silicon, boron, carbon, hydrogen, and nitrogen. The encapsulation layer 22 can be formed by deposition of a continuous layer of the dielectric material that provides the encapsulation layer 22. The depositing can include, but is not limited to, CVD, PECVD, PVD, ALD or spin-on coating. The encapsulation layer 22 can have a thickness from 10 nm to 200 nm. Other thicknesses are possible and can be employed as the thickness of the encapsulation layer 22.

Referring now to FIG. 9, there is illustrated the exemplary structure shown in FIG. 8 after forming a second ILD layer 24 having a via contact structure 26 embedded therein, and forming a second electrically conductive layer 28 on physically exposed surfaces of each of the second ILD layer 24 and the via contact structure 26. Note that the via contact structure 26 is formed in the second ILD layer 24 and the encapsulation layer 22. The second ILD layer 24 can include one of the dielectric materials mentioned above for providing the first ILD layer 12. In some embodiments, the dielectric material that provides the second ILD layer 24 can be compositionally the same as the dielectric material that provides the first ILD layer 12. In some embodiments, the dielectric material that provides the second ILD layer 24 can be compositionally different than the dielectric material that provides the first ILD layer 12. The second ILD layer 24 can be formed by a deposition process such, as for example, CVD, PECVD or spin-on coating. A planarization process can be performed after the deposition of the dielectric material that provides the second ILD layer 24.

The via contact structure 26 can be formed utilizing a metallization process in which a via opening is formed by lithography and etching, and thereafter the via opening is filled (including deposition and planarization) with at least a contact conductive metal such as W, Cu, Al, Co, Ru, Mo, Os, Ir, Rh, or an alloy thereof. In some embodiment, the via contact structure 26 can also include a silicide liner, such as Ni, Pt, NiPt, and/or an adhesion metal liner, such as TiN, and the conductive metal. The via contact structure 26 can also include one or more contact liners (not shown). In one or more embodiments, the contact liner (not shown) can include a diffusion barrier material. Exemplary diffusion barrier materials include, but are not limited to, Ti, Ta, Ni, Co, Pt, W, Ru, TiN, TaN, WN, WC, an alloy thereof, or a stack thereof such as Ti/TiN and Ti/WC. In one or more embodiments in which a contact liner is present, the contact liner (not shown) can include a silicide liner, such as Ti, Ni, NiPt, etc., and a diffusion barrier material, as defined above. The via contact structure 26 has a first surface (i.e., bottommost as depicted in FIG. 9) that is in electrical contact with the second electrode structure 20S and a second surface (i.e., the topmost surface as depicted in FIG. 9) that is in electrical contact with the second electrically conductive layer 28.

The second electrically conductive layer 28 is composed of one of the electrically conductive materials (i.e., electrically conductive metals or electrically conductive metal alloys) as mentioned above for the first electrically conductive layer 10. The second electrically conductive layer 28 can be composed of a single electrically conductive material or a multilayered stack of at least two different electrically conductive materials. The electrically conductive material that provides the second electrically conductive layer 28 can be compositionally the same as, or compositionally different from, the electrically conductive material that provides the first electrically conductive layer 10. The second electrically conductive layer 28 can be formed by a deposition process such as, for example, CVD, PECVD, ALD, PVD, sputtering, chemical solution deposition or plating.

FIG. 9 illustrates a ReRAM including first electrode structure 16S having asymmetry and an angled profile defined by a slanted surface, memory switching layer 18 on the first electrode structure 16S, and a second electrode structure 20S located on the memory switching layer 18. As is shown, the slanted surface of the first electrode 16SA interfaces with the memory switching layer 18. As is further shown, the top of the ReRAM is in electrical contact with the second electrically conductive layer 28 by means of the via contact structure 26, and a bottom of the ReRAM is in electrical contact with the first electrically conductive layer 10. In this embodiment, the forming area would be through the entire length of the memory switching layer 18 that interfaces with the slanted surface of the bottom electrode structure 16S.

Referring now to FIG. 10, there is illustrated the exemplary structure shown in FIG. 3 after performing a rotating angled etching process to convert the first electrode pillar 16 into a first electrode structure 16S having an angled profile. In this embodiment, the angled profile includes a plurality of sloping surfaces that converge at a point. Angled etching with rotation provides a symmetrical, solid, bottom electrode structure 16S having an angled profile that ends at a point (or tip) as shown in FIG. 10. By “symmetrical” is it meant two sides or halves of the structure, as designated by a vertical line passing through a middle portion, i.e., the point (i.e., tip) of the structure are the same. The angled profile provides more forming area, which can reduce forming voltages without causing area penalty. The point (or tip) provides for a more controlled location for the filament forming process to occur in the memory switching layer 18 that interfaces with the symmetrical bottom electrode structures of this embodiment of the present application.

In this embodiment of the present application, the wafer including the structure illustrated in FIG. 3 is rotated during angled etching. This rotating angled etching process can provide different types of first electrode structures 16S some of which are depicted in FIGS. 11A, 11B, 11C, 11D and 11E. Notably, FIG. 11A shows a first electrode structure 16S that is flamed shaped; such a first electrode structure 16S can be formed using 0°, 180° angled RIE. FIG. 11B shows a first electrode structure 16S that is triangular pyramid shaped; such a first electrode structure 16S can be formed using 0°, 120°, 240° angled RIE. FIG. 11C shows a first electrode structure 16S that is square pyramid shaped; such a first electrode structure 16S can be formed using 0°, 90°, 180°, 270° angled RIE. FIG. 11D shows a first electrode structure 16S that is multiple faceted pyramid shaped; such a first electrode structure 16S can be formed using 0°, 360°/N times, wherein N is 1, 2, 3, etc. angled RIE. FIG. 11E shows a first electrode structure 16S that is cone shaped; such a first electrode structure 16S can be formed using a continuous angled 0° approximately 360° RIE. The angles listed represent the angles in which the wafer is rotated and where the angled etching process occurs.

Referring now to FIG. 12A, there is illustrated the exemplary structure shown in FIG. 10 after further ReRAM device processing. Further ReRAM device processing includes the processing as described in FIGS. 5-9 above. The further ReRAM device processing forms a ReRAM including first electrode structure 16S having an angled profile including slanted surfaces that converge at a point, memory switching layer 18 on the first electrode structure 16S, and a second electrode structure 20S located on the memory switching layer 18. A top of the ReRAM is in electrical contact with the second electrically conductive layer 28 by means of via contact structure 26, and a bottom of the ReRAM is in electrical contact with the first electrically conductive layer 10. At this point of the present application, no forming voltage has been applied to the structure.

Referring now to FIG. 12B, there is depicted an enlarged view of first electrode structure 16S, memory switching layer 18, and second electrode structure 20 shown in FIG. 12A and depicting a filament forming area (labeled as formed filament in FIG. 12B) created by applying a forming voltage to the structure. In addition to providing an increased forming area as compared with a conventional first electrode structure that has an entirely planar forming surface, which in turn can reduce forming voltage without area penalty, ReRAMs including the first electrode structure 16S having an angled profile including slanted surfaces that converge at a point provide a controlled location for formation of the filament. In ReRAMs including the first electrode structure 16S having an angled profile including slanted surfaces that converge at a point, the point (or tip) surface function as a lightning rod such that filament formation can be localized which can grow upward within the memory switching liner 18 from the point (or tip) of the first electrode structure 16S. As the electric filed is highest at the point (i.e., tip) of the first electrode structure 16S, forming voltage can be lowered (in this embodiment, there is no dependency on electrode area). Since the filament formation is controlled in this embodiment of the present application, uniform regular memory switching cycles can be obtained.

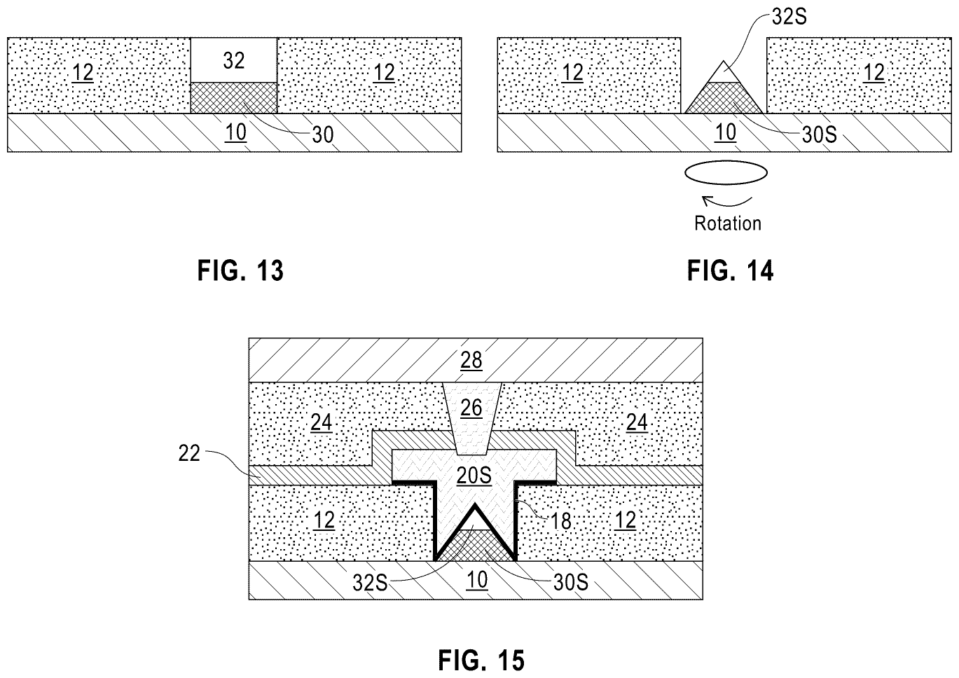

Referring now to FIG. 13, there is illustrated another exemplary structure in accordance with the present application. This another exemplary structure illustrated in FIG. 13 includes a first electrically conductive layer 10, as defined above, a first ILD layer 12, as defined above, and having an opening formed therein, and a bilayer structure 30/32 present in the opening, the bilayer structure 30/32 includes a bottom first conductive electrode material layer 30 and a top first conductive electrode material layer 32. In this embodiment, the bottom first conductive electrode material layer 30 and the top first conductive electrode material layer 32 are each composed of one of the electrode materials mentioned above for the first conductive electrode material layer 16L, with the proviso that the electrode material that provides the bottom first conductive electrode material layer 30 is compositionally different from the electrode material that provides the top first conductive electrode material layer 32.

The bilayer structure 30/32 is formed in the opening that is present in the first ILD layer 12 by first depositing a first electrode material that will define the bottom first conductive electrode material layer 30. A planarization process can follow the deposition of this first electrode material and then a recess etch can be used to provide the bottom first conductive electrode material layer 30. A second electrode material that will define the top first conductive electrode material layer 32 will then be formed by deposition, and thereafter the second electrode material will be subjected to a planarization process so as to provide the top first conductive electrode material layer 32. As is illustrated in FIG. 13, each of the bottom first conductive electrode material layer 30 and the top first conductive electrode material layer 32 (and thus the bilayer structure 30/32) is present in the opening formed in the first ILD layer 12. In this embodiment, the bottom first conductive electrode material layer 30 is in physical contact with the first electrically conductive layer 10 and a topmost surface of the top first conductive electrode material layer 32 is substantially coplanar with a topmost surface of the first ILD layer 12.

Referring now to FIG. 14, there is illustrated the exemplary structure shown in FIG. 13 after performing a rotating angled etching process, as discussed above, to convert the bilayer structure 30/32 into a first electrode bilayer structure 30S/32S having an angled profile. In this embodiment, the first electrode bilayer structure 30S/32S includes a bottom first electrode structure 30S (which functions as a base), and a top first electrode structure 32S which has the angled profile including the point (or tip), which will function as the area in which filament forming will occur. The top first electrode structure 32S is designed to have a small apex curvature. The small apex curvature can interact with the memory switching layer 18 enabling an oxygen vacancy control for a better memory switching event. In some embodiments, the electrode material of the bottom first conductive electrode material layer 30 has a higher conductance than the electrode material that provides the top first conductive electrode material layer 32. Due to these material different properties the sidewalls of the bottom first electrode structure 30S can have different angles than the sidewalls of the top first electrode structure 32S.

Referring now to FIG. 15, there is illustrated the exemplary structure shown in FIG. 14 after further ReRAM device processing. Further ReRAM device processing includes the processing as described in FIGS. 5-9 above. The further ReRAM device processing forms a ReRAM including first electrode bilayer structure 30S/32S having an angled profile including slanted surfaces that converge at a point (or tip), memory switching layer 18 on the first electrode bilayer structure 30S/32S, and a second electrode structure 20S located on the memory switching layer 18. A top of the ReRAM is in electrical contact with the second electrically conductive layer 28 by means of via contact structure 26, and a bottom of the ReRAM, i.e., the first bottom electrode structure 30S, is in electrical contact with the first electrically conductive layer 10. At this point of the present application, no forming voltage has been applied to the structure.

In addition to providing an increased forming area as compared with a conventional first electrode structure that has an entirely planar forming surface, which in turn can reduce forming voltage without area penalty, ReRAMs including the first electrode bilayer structure 30S/32S having an angled profile including the point (or tip) provides a controlled location for formation of the filament. In ReRAMs including the first electrode bilayer structure 30S/32S having an angled profile including the point (or tip), this point functions as a lightning rod such that filament formation can be localized which can grow upward from the point of the first electrode bilayer structure 30S/32S, i.e., within the top first electrode structure 32S. As the electric filed is highest at the point (i.e., tip) of the first electrode bilayer structure 30S/32S, forming voltage can be lowered (in this embodiment, there is no dependency on electrode area).

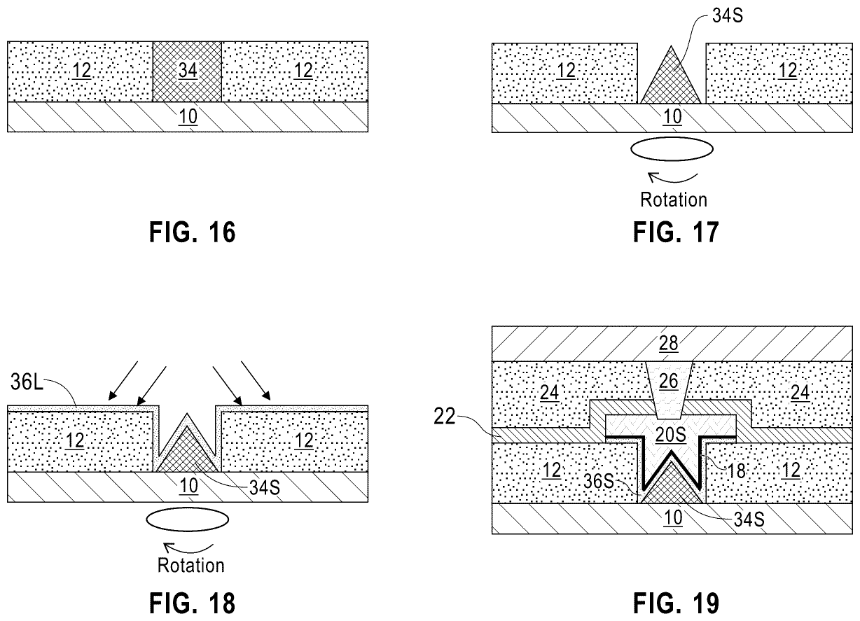

Referring now to FIG. 16, there is illustrated another exemplary structure in accordance with the present application. This another exemplary structure illustrated in FIG. 16 includes a first electrically conductive layer 10, as defined above, a first ILD layer 12, as defined above, having an opening formed therein, and a bottom first conductive electrode pillar 34 in the opening. The first bottom first conductive electrode pillar 34 of this embodiment of the present application is equivalent to the first electrode pillar 16 mentioned above in a previous embodiment of the present application. The first bottom first conductive electrode pillar 34 can include one of the electrode materials mentioned above for the first conductive electrode material layer 16L and the first bottom first conductive electrode pillar 34 can be formed utilizing the same processing technique as mentioned above in forming the first electrode pillar 16. In some embodiments, the electrode material that provide the first bottom first conductive electrode pillar 34 is of high conductance (as compared to the electrode material that will be subsequently used in forming a bottom second conductive electrode layer 36L as shown in FIG. 18).

Referring now FIG. 17, there is illustrated the exemplary structure shown in FIG. 16 after performing a rotating angled etching process, as discussed above, to convert the bottom first conductive electrode pillar 34 into a first bottom conductive electrode structure 34S having an angled profile.

Referring now to FIG. 18, there is illustrated the exemplary structure shown in FIG. 17 after forming a bottom second conductive electrode layer 36L via an angled deposition process or by a conformal deposition process. The bottom second conductive electrode layer 36L is composed of one of the electrode materials mentioned above for the first conductive electrode material layer 16L. The electrode material that provides the bottom second conductive electrode layer 36L is typically, but not necessarily always, compositionally different from the electrode material that is used in providing the first bottom conductive electrode structure 34S. The angled deposition includes rotating the wafer while deposing the electrode material. Two different angles are typically used for this deposition. The depositing can include, for example, angled CVD or angled PECVD. When a conformal deposition is employed, the deposited can be PVD. The bottom second conductive electrode layer 36L can have a thickness from 10 nm to 100 nm; although other thickness that are below 10 nm and above 100 nm can be employed. The bottom second conductive electrode layer 36L is formed as a continuous layer that follows the contour of the exemplary structure shown in FIG. 17.

Referring now to FIG. 19, there is illustrated the exemplary structure shown in FIG. 18 after further ReRAM device processing. Further ReRAM device processing includes the processing as described in FIGS. 5-9 above. Note that the patterning of the second conductive material layer and the memory switching layer to provide a second electrode structure and a memory switching layer, respectively, also includes patterning the bottom second conductive electrode layer 36L to provide a bottom second electrode structure 36S; the bottom second electrode structure 36S structure can be referred to a bottom second electrode liner as well.

The further ReRAM device processing forms a ReRAM including first electrode bilayer structure 34S/36S having an angled profile including slanted surfaces that converge at a point, memory switching layer 18 on the first electrode bilayer structure 34S/36S, and a second electrode structure 20S located on the memory switching layer 18. A top of the ReRAM is in electrical contact with the second electrically conductive layer 28 by means of via contact structure 26, and a bottom of the ReRAM, i.e., the first bottom electrode structure 34S, is in electrical contact with the first electrically conductive layer 10. The ReRAM shown in FIG. 19 has all of the advantages of the ReRAM depicted in FIGS. 12A-12B and 15.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A memory structure comprising:
an asymmetrical first electrode structure having a slanted surface;
a memory switching layer forming an interface with the slanted surface of the asymmetrical first electrode structure; and
a second electrode structure located on the memory switching layer.

2. The memory structure of claim 1, wherein the slanted surface of the asymmetrical first electrode structure extends in a direction from a topmost surface down to a planar sub-surface of the asymmetrical first electrode structure.

3. The memory structure of claim 1, wherein the direction is from left to right.

4. The memory structure of claim 1, wherein the direction is from right to left.

5. The memory structure of claim 1, further comprising a first electrically conductive layer in electrical contact with the asymmetrical first electrode structure, and a second electrically conductive layer in electrical contact with the second electrode structure by means of a via contact structure.

6. The memory structure of claim 5, further comprising an encapsulation layer located adjacent to the memory switching layer, the second electrode structure and the via contact structure.

7. The memory structure of claim 6, wherein the asymmetrical first electrode structure, a first portion of the memory switching layer, and a first portion of the second electrode structure are present in a first interlayer dielectric layer, and the first interlayer dielectric layer is located on a surface of the first electrically conductive structure.

8. The memory structure of claim 7, further comprising a second interlayer dielectric layer located above the first interlayer dielectric layer and adjacent to a second portion of the memory switching layer, a second portion of the second electrode structure and the via contact structure, wherein the second electrically conductive layer is located on top of the second interlayer dielectric layer.

9. The memory structure of claim 1, wherein the memory switch layer has a sidewall that is vertically aligned with a sidewall of the second electrode structure.

10. A memory structure comprising:
a symmetrical first electrode structure having an angled profile comprising a plurality of slanted surfaces that converge into a point;
a memory switching layer forming an interface with the angled profile of the symmetrical first electrode structure; and
a second electrode structure located on the memory switching layer.

11. The memory structure of claim 10, wherein the symmetrical first electrode is in the shape of a flame, a triangular pyramid, a square pyramid, a multiple faceted pyramid or a cone.

12. The memory structure of claim 11, wherein the symmetrical first electrode is solid and composed of a single electrode material.

13. The memory structure of claim 11, wherein the symmetrical first electrode comprises a bilayer structure of a bottom first electrode structure, and a top first electrode structure.

14. The memory structure of claim 11, wherein the symmetrical first electrode comprises a bilayer structure of a first bottom electrode structure and a bottom second electrode structure.

15. The memory structure of claim 10, further comprising a first electrically conductive layer in electrical contact with the symmetrical first electrode structure, and a second electrically conductive layer in electrical contact with the second electrode structure by means of a via contact structure.

16. The memory structure of claim 15, further comprising an encapsulation layer located adjacent to the memory switching layer, the second electrode structure and the via contact structure.

17. The memory structure of claim 16, wherein the symmetrical first electrode structure, a first portion of the memory switching layer, and a first portion of the second electrode structure are present in a first interlayer dielectric layer, and the first interlayer dielectric layer is located on a surface of the first electrically conductive structure.

18. The memory structure of claim 17, further comprising a second interlayer dielectric layer located above the first interlayer dielectric layer and adjacent to a second portion of the memory switching layer, a second portion of the second electrode structure and the via contact structure, wherein the second electrically conductive layer is located on top of the second interlayer dielectric layer.

19. A method of forming a memory structure, the method comprising:
forming a first electrode pillar in an opening located in an interlayer dielectric layer;
performing an angled etching process to convert the first electrode pillar into a first electrode structure having an angled profile;
forming a memory switching liner on physically exposed surfaces of the first electrode structure and the first interlayer dielectric layer;
forming a conductive electrode material layer on the memory switching liner; and
patterning the conductive material layer and the memory switching liner to provide a second electrode structure and a memory switching layer, respectively.

20. The method of claim 19, wherein the angled etching process is performed with rotation.
